(19) United States
(12) Patent Application Publication
(10) Pub. No.: US 2023/0298939 A1
(43) Pub. Date: Sep. 21, 2023

(54) CHIP MANUFACTURING METHOD

(71) Applicant: DISCO CORPORATION, Tokyo (JP)

(72) Inventor: Yu ZHAO, Tokyo (JP)

(21) Appl. No.: 18/178,794

(22) Filed: Mar. 6, 2023

(30) Foreign Application Priority Data
Mar. 16, 2022 (JP) 2022-040931

(51) Int. Cl. H01L 21/78; H01L 21/268; H01L 21/3065

(52) U.S. Cl. CPC H01L 21/78; H01L 21/268; H01L 21/3065

(57) ABSTRACT

After damaged portions in the vicinity of side surfaces and bottom surfaces of grooves formed in a groove forming step are removed in a first plasma etching step, the side surfaces of the grooves are coated with a second protective film formed in a second coating step. As a result, in a dividing step in which the wafer is subjected to plasma etching, undercut which would progress from the side surfaces of the grooves can be prevented.

### BACKGROUND OF THE INVENTION

### Field of the Invention

The present invention relates to a chip manufacturing method for dividing a wafer formed with a plurality of devices along boundaries of the plurality of devices to manufacture individual chips.

### Description of the Related Art

Chips of devices such as integrated circuits (ICs) are constituent elements indispensable for various types of electronic equipment such as a mobile phone and a personal computer. Such chips are manufactured, for example, by dividing a wafer formed with a plurality of devices along the boundaries of the plurality of devices.

As a method for dividing the wafer in this way, subjecting the wafer to plasma etching after providing a mask on the wafer such that the boundaries are exposed has been proposed (refer to, for example, Japanese Patent Laid-open No. 2016-207737). This mask is formed, for example, by coating the whole region of a front surface of the wafer with a water-soluble protective film, and thereafter, applying a laser beam to the wafer along the boundaries to remove part of the protective film.

### SUMMARY OF THE INVENTION

In a case where the mask is formed as above-described, grooves are formed also in the front surface of the wafer, and portions in the vicinity of side surfaces and bottom surfaces of the grooves are damaged. Hence, when this wafer is subjected to plasma etching so as to divide the wafer along the boundaries of the plurality of devices, etching (undercut) may progress from the damaged portions in the vicinity of the side surfaces and the bottom surfaces of the grooves in a direction parallel to the front surface of the wafer.

Besides, when the undercut progresses, part of the mask formed on the front surface of the wafer is removed, and it may be difficult to protect the devices formed on the wafer. In view of this, it is an object of the present invention to provide a chip manufacturing method by which it is possible to manufacture chips by dividing a wafer without permitting the progress of the undercut.

In accordance with an aspect of the present invention, there is provided a chip manufacturing method for dividing a wafer formed with a plurality of devices along boundaries of the plurality of devices to manufacture individual chips. The chip manufacturing method includes a first coating step of coating a front surface of the wafer with a water-soluble first protective film, a groove forming step of applying, after the first coating step, a laser beam of such a wavelength as to be absorbed in the wafer to the wafer through the first protective film such that regions of the first protective film overlapping with the boundaries and regions on the front surface side of the wafer overlapping with the boundaries are removed and grooves are formed in the wafer, a first plasma etching step of subjecting, after the groove forming step, the wafer to isotropic plasma etching from the front surface side of the wafer in a state in which the grooves are exposed, a second coating step of, after the first plasma etching step, coating side surfaces and bottom surfaces of the grooves with a second protective film, and a dividing step of sequentially repeating, after the second coating step, a second plasma etching step of subjecting the wafer to anisotropic plasma etching from the front surface side of the wafer so as to expose the bottom surfaces of the grooves, a third plasma etching step of subjecting the wafer to isotropic plasma etching from the front surface side of the wafer, and a third coating step of coating the side surfaces and the bottom surfaces of the grooves with a third protective film thinner than the second protective film, until the wafer is divided along the boundaries.

In accordance with another aspect of the present invention, there is provided a chip manufacturing method for dividing a wafer formed with a plurality of devices along boundaries of the plurality of devices to manufacture individual chips. The chip manufacturing method includes a first coating step of coating a front surface of the wafer with a water-soluble first protective film, a groove forming step of applying a laser beam of such a wavelength as to be absorbed in the wafer to the wafer through the first protective film such that regions of the first protective film overlapping with the boundaries and regions on the front surface side of the wafer overlapping with the boundaries are removed and grooves are formed in the wafer, after the first coating step, a first plasma etching step of subjecting the wafer to isotropic plasma etching from the front surface side of the wafer in a state in which the grooves are exposed, after the groove forming step, a second coating step of coating side surfaces and bottom surfaces of the grooves with a second protective film, after the first plasma etching step, and a dividing step of subjecting the wafer to anisotropic plasma etching from the front surface side of the wafer, until the wafer is divided along the boundaries, after the second coating step.

Further, in accordance with the other aspect of the present invention, preferably, the chip manufacturing method may further include a second plasma etching step of subjecting the wafer to anisotropic plasma etching from the front surface side of the wafer so as to expose the bottom surfaces of the grooves, after the second coating step and before the dividing step, and conditions for the anisotropic plasma etching may be different between the second plasma etching step and the dividing step.

In addition, in the present invention, preferably, the wafer may include a substrate, and an insulating layer provided between the substrate and the plurality of devices.

In addition, in the present invention, preferably, the second protective film may have an insulating property.

Besides, in the present invention, preferably, the second protective film may contain carbon fluoride.

In addition, in the present invention, preferably, a thickness of the second protective film may be 20 nm or more.

In the present invention, damaged portions in the vicinity of side surfaces and bottom surfaces of the grooves formed in the groove forming step are removed in the first plasma etching step, and thereafter the side surfaces of the grooves are coated with the second protective film formed in the second coating step. As a result, in the dividing step in which the wafer is subjected to plasma etching, the undercut which would progress from the side surfaces of the grooves can be prevented.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view depicting schematically an example of a frame unit including a wafer;

FIG. 1B is a sectional view depicting schematically a cross-section of the frame unit depicted in FIG. 1A;

FIG. 2 is a flow chart depicting schematically an example of a chip manufacturing method for dividing the wafer along boundaries of a plurality of devices to manufacture individual chips;

FIG. 3A is a sectional view depicting schematically a manner of a first coating step;

FIG. 3B is a partial enlarged sectional view depicting schematically the wafer after the first coating step;

FIG. 4A is a sectional view depicting schematically a manner of a groove forming step;

FIG. 4B is a partial enlarged sectional view depicting schematically the wafer after the groove forming step;

FIG. 5 is a diagram depicting schematically an example of a plasma generating apparatus;

FIG. 6A is a partial enlarged sectional view depicting schematically the wafer after a first plasma etching step;

FIG. 6B is a partial enlarged sectional view depicting schematically the wafer after a second coating step;

FIG. 7 is a flow chart depicting schematically a specific example of a dividing step; and

FIG. 8 is a partial enlarged sectional view depicting schematically the wafer after the dividing step.

### DETAILED DESCRIPTION OF THE PREFERRED EMBODIMENT

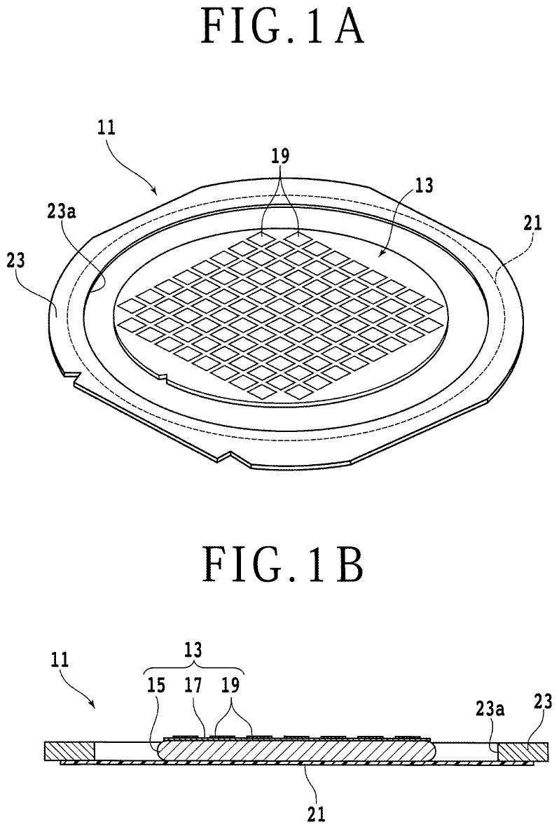

An embodiment of the present invention will be described with reference to the attached drawings. FIG. 1A is a perspective view depicting schematically an example of a frame unit including a wafer, and FIG. 1B is a sectional view depicting schematically a cross-section of the frame unit depicted in FIG. 1A. The frame unit 11 depicted in FIGS. 1A and 1B includes a wafer 13 utilized for manufacture of chips.

The wafer 13 has a substrate 15 formed of, for example, silicon (Si), silicon carbide (SiC), gallium nitride (GaN), or the like. An insulating layer 17 formed of, for example, silicon oxide (SiO₂), silicon nitride (Si₃N₄), or the like is provided on a front surface of the substrate 15.

Further, a plurality of mutually independent devices 19 are provided on the front surface side of the wafer 13. The plurality of devices 19 are arranged in a matrix pattern on a front surface of the insulating layer 17. In other words, boundaries of the plurality of devices 19 extend in a grid pattern.

In addition, to a back surface of the wafer 13, that is, to a back surface of the substrate 15, a central region of a disk-shaped tape 21 larger than the substrate 15 in diameter is adhered. The tape 21 includes, for example, a flexible film-shaped base material layer and an adhesive layer (glue layer) provided on one surface (a surface on the substrate 15 side) of the base material layer.

Specifically, the base material layer is formed of polyolefin (PO), polypropylene (PP), polyethylene terephthalate (PET), polyvinyl chloride (PVC), polystyrene (PS), or the like. Besides, the adhesive layer is formed of a UV-curing silicone rubber, an acrylic material, an epoxy material, or the like.

In addition, an annular frame 23 formed with a circular opening larger than the wafer 13 in diameter is adhered to a peripheral region of the tape 21. The frame 23 is formed of, for example, a metallic material such as aluminum (Al).

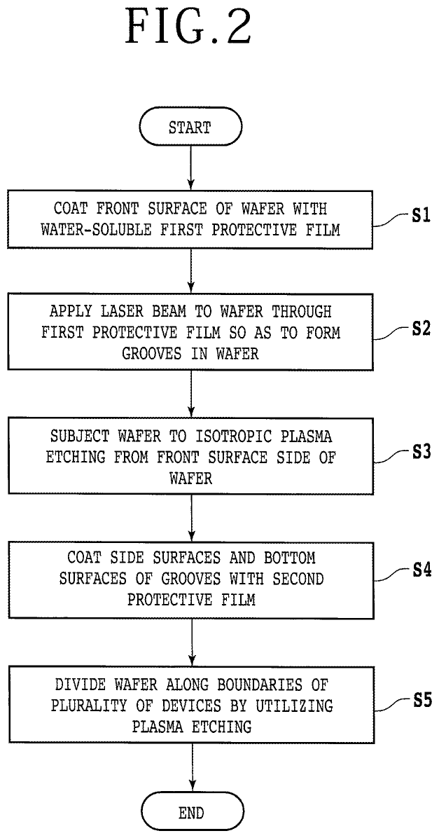

FIG. 2 is a flow chart depicting schematically an example of a chip manufacturing method for dividing the wafer 13 along the boundaries of the plurality of devices 19 to manufacture individual chips. In the method, first, the front surface of the wafer 13 is coated with a water-soluble protective film (first protective film) (first coating step: S1).

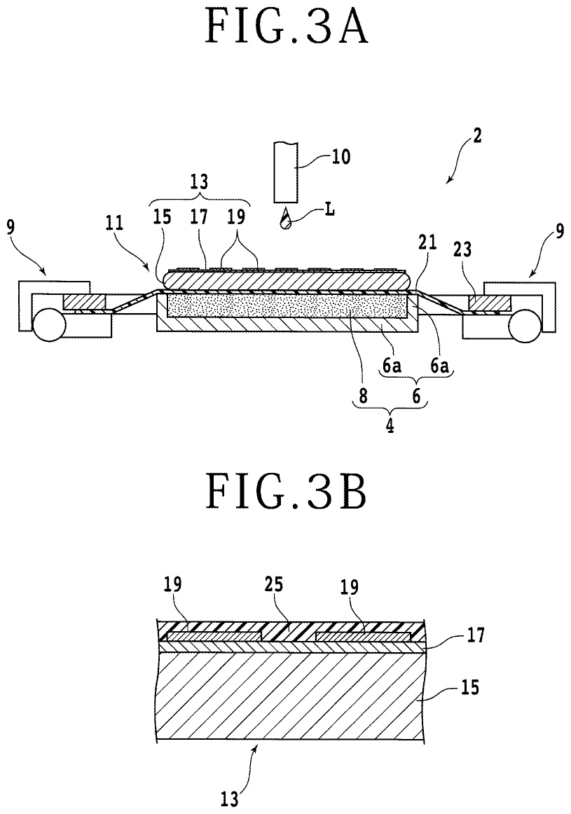

FIG. 3A is a side view depicting schematically a manner of the first coating step (S1), and FIG. 3B is a partial enlarged sectional view depicting schematically the wafer 13 after the first coating step (S1). The first coating step (S1) is carried out, for example, by utilizing a coater 2 depicted in FIG. 3A. The coater 2 has a holding table 4.

The holding table 4 has a disk-shaped frame body 6 formed of ceramic or the like. The frame body 6 includes a disk-shaped bottom wall 6a, and a cylindrical side wall 6b erected from a peripheral edge section of the bottom wall 6a. In other words, on an upper surface side of the frame body 6, a disk-shaped recess defined by the bottom wall 6a and the side wall 6b is formed.

Besides, a disk-shaped porous plate 8 which has a diameter substantially equal to the diameter of the recess is fixed in the recess formed on the upper surface side of the frame body 6. The porous plate 8 is formed of, for example, a porous ceramic. When the frame unit 11 is loaded into the coater 2, the wafer 13 is placed on an upper surface of the holding table 4 with the tape 21 interposed therebetween.

In addition, a plurality of clamps 9 are provided in the periphery of the holding table 4. The plurality of clamps 9 are provided at substantially regular intervals along the circumferential direction of the holding table 4. When the frame unit 11 is loaded into the coater 2, the plurality of clamps 9 grasp the frame 23 at a position lower than the upper surface of the holding table 4.

Besides, the porous plate 8 of the holding table 4 communicates with a suction source (not illustrated) such as an ejector through a through-hole formed in the bottom wall 6a of the frame body 6. When the suction source is operated in a state in which the frame unit 11 has been loaded into the coater 2, a suction force acts on the wafer 13 through the tape 21, whereby the wafer 13 is held by the holding table 4.

In addition, the holding table 4 and the plurality of clamps 9 are connected to a rotational drive source (not illustrated) such as a motor. When the rotational drive source is operated, the holding table 4 and the plurality of clamps 9 are rotated around a rotational axis which is a straight line passing through the center of the upper surface of the porous plate 8 and being along a vertical direction.

Further, above the holding table 4, there is provided a resin supply nozzle 10 which supplies a liquid resin L onto the front surface of the wafer 13 included in the frame unit 11 held by the holding table 4. The liquid resin L is, for example, a solution including a water-soluble resin such as polyvinylpyrrolidone or polyvinyl alcohol and an organic solvent such as propylene glycol monomethyl ether.

Note that the water-soluble resin becomes a main constituent of a protective film formed by drying the liquid resin L. In addition, the organic solvent lowers the surface tension of the liquid resin L, and suppresses unevenness of coating when the liquid resin L is coated to the wafer 13.

Besides, a light absorbing agent such as ferulic acid may be added to the liquid resin L. This light absorbing agent absorbs a laser beam, described later, to generate laser ablation in the protective film.

The above-described coater 2 forms a protective film on the front surface of the wafer 13 held by the holding table 4 with the tape 21 interposed therebetween, by a spin coating method. Specifically, a predetermined amount of the liquid resin L is supplied from the resin supply nozzle 10 to the vicinity of the center of the front surface of the wafer 13, and then, the holding table 4 is rotated at a predetermined speed (for example, 1,500 rpm or more and 3,000 rpm or less).

As a result, the whole region of the front surface of the wafer 13 is coated with the liquid resin L. After the rotation of the holding table 4 is stopped, the liquid resin L is dried. As a result, a water-soluble protective film (first protective film) 25 covering the front surface of the wafer 13 is formed (see FIG. 3B).

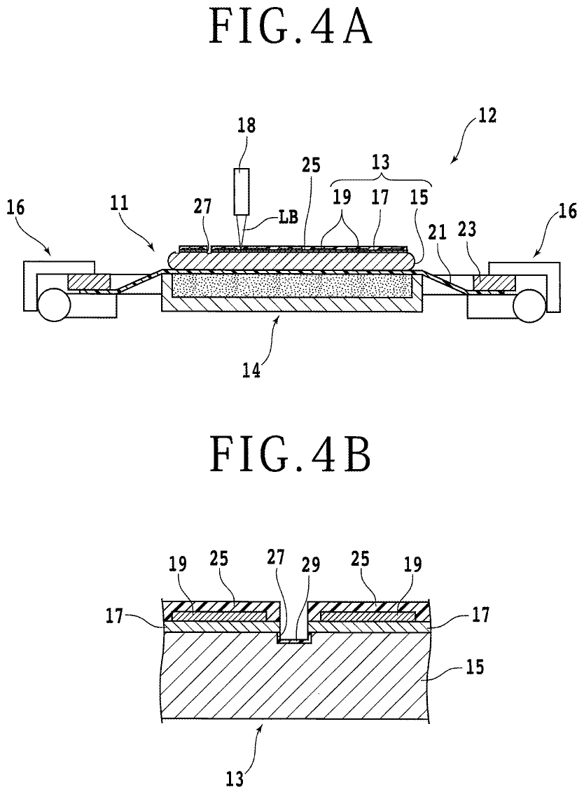

After the first coating step (S1), a laser beam is applied to the wafer 13 through the protective film (first protective film) 25 such that regions on the front surface side of the wafer 13 are removed and grooves are formed in the wafer 13 (groove forming step: S2). FIG. 4A is a sectional view depicting schematically a manner of the groove forming step (S2), and FIG. 4B is a partial enlarged sectional view depicting schematically the wafer 13 after the groove forming step (S2).

The groove forming step (S2) is carried out by utilizing a laser processing apparatus 12 depicted in FIG. 4A. The laser processing apparatus 12 includes a holding table 14 which has a structure similar to that of the above-described holding table 4, and clamps 16 having a structure similar to that of the above-described clamps 9. Besides, the holding table 14 communicates with a suction source (not illustrated) such as an ejector, similarly to the above-described holding table 4.

In addition, the holding table 14 is connected to a horizontal direction moving mechanism (not illustrated). The horizontal direction moving mechanism includes, for example, a ball screw, a motor, and the like. When the horizontal direction moving mechanism is operated, the holding table 14 is moved along a horizontal direction (for example, a front-rear direction and/or a left-right direction).

Further, a head 18 of a laser applying unit is provided above the holding table 14. The laser applying unit has a laser oscillator (not illustrated) that generates a laser beam LB of such a wavelength (for example, 355 nm) as to be absorbed in the wafer 13. The laser oscillator has, for example, a neodymium-doped yttrium aluminum garnet (Nd:YAG) or the like as a laser medium.

Besides, the head 18 accommodates an optical system such as a condenser lens and a mirror. When the laser beam LB is generated in the laser oscillator, the laser beam LB is applied toward the holding table 14 through the optical system accommodated in the head 18.

In the above-described laser processing apparatus 12, in a state in which the wafer 13 formed on the front surface thereof with the first protective film 25 is held on the holding table 14 through the tape 21, the laser beam LB is applied along the boundaries of the plurality of devices 19, whereby grooves 27 are formed in the front surface of the wafer 13. Specifically, while the laser beam LB is being applied from the head 18 toward the wafer 13, the horizontal direction moving mechanism is operated in such a manner that the laser beam LB is applied along the boundaries of the plurality of devices 19 (see FIG. 4A).

As a result, laser ablation is generated in the vicinity of the front surface of the wafer 13, whereby regions of the first protective film 25 overlapping with the boundaries of the plurality of devices 19 and regions in the vicinity of the front surface of the wafer 13 (regions of the insulating layer 17 and regions in the vicinity of the front surface of the substrate 15) which overlap with the boundaries of the plurality of devices 19 are removed. As a result, grooves 27 are formed in the wafer 13, and portions 29 in the vicinity of side surfaces and bottom surfaces of the grooves 27 are damaged (see FIG. 4B).

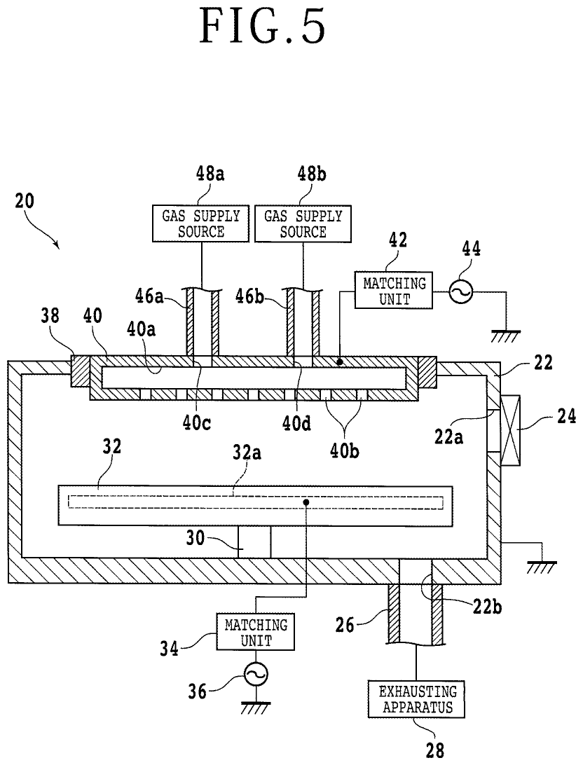

After the groove forming step (S2), the wafer 13 is subjected to isotropic plasma etching from the front surface side of the wafer 13 (first plasma etching step: S3). FIG. 5 is a diagram depicting schematically an example of a plasma generating apparatus utilized for carrying out the first plasma etching step (S3).

The plasma generating apparatus 20 depicted in FIG. 5 has a chamber 22 which is formed of a conductive material and is grounded. The chamber 22 is formed with a loading/unloading port 22a through which the frame unit 11 is loaded into the chamber 22 and the frame unit 11 is unloaded from the chamber 22.

At the loading/unloading port 22a, a gate valve 24 capable of establishing communication between the inside space and the outside space of the chamber 22 or shutting off the communication is provided. In addition, the chamber 22 is formed with an exhaust port 22b for exhausting the inside space.

The exhaust port 22b communicates with an exhausting apparatus 28 such as a vacuum pump through a piping 26 and the like. In addition, a support member 30 is provided on an inside surface of the chamber 22, and the support member 30 supports a table 32.

Besides, an electrostatic chuck (not illustrated) is provided at an upper portion of the table 32. In addition, a disk-shaped electrode 32a located on the lower side of the electrostatic chuck is provided inside the table 32. The electrode 32a is connected to a high-frequency power source 36 through a matching unit 34.

Besides, the chamber 22 is formed with a disk-shaped opening at a position opposed to the upper surface of the table 32, and a gas ejecting head 40 supported by the chamber 22 through a bearing 38 is provided at the opening. The gas ejecting head 40 is formed of a conductive material, and is connected to a high-frequency power source 44 through a matching unit 42.

In addition, a cavity (gas diffusion space) 40a is formed inside the gas ejecting head 40. Besides, an inside portion (for example, a lower portion) of the gas ejecting head 40 is formed with a plurality of gas ejection ports 40b that establish communication between the gas diffusion space 40a and the inside space of the chamber 22. In addition, an outside portion (for example, an upper portion) of the gas ejecting head 40 is formed with two gas supply ports 40c and 40d for supplying predetermined gases into the gas diffusion space 40a.

The gas supply port 40c communicates with a gas supply source 48a for suppling a carbon fluoride gas such as C₄F₈ and/or a sulfur fluoride gas such as SF₆ through a piping 46a and the like. In addition, the gas supply port 40d communicates with a gas supply source 48b for suppling an inert gas such as Ar and O₂ gases or the like through a piping 46b and the like, for example.

In the above-described plasma generating apparatus 20, the isotropic plasma etching applied to the wafer 13 from the front surface side of the wafer 13 is carried out, for example, as follows. Specifically, first, in a state in which the gate valve 24 establishes communication between the inside space and the outside space of the chamber 22, the frame unit 11 is loaded onto the table 32 such that the tape 21 faces downward.

Next, the wafer 13 is held by the electrostatic chuck of the table 32 through the tape 21. Subsequently, the inside space of the chamber 22 is exhausted by the exhausting apparatus 28, to establish a vacuum state. Next, in a state in which a gas containing SF₆ is supplied from the gas supply source 48a into the inside space of the chamber 22 and an Ar gas is supplied from the gas supply source 48b into the inside space, high-frequency electric power is supplied from the high-frequency power source 44 to the gas ejecting head 40, over a predetermined period of time.

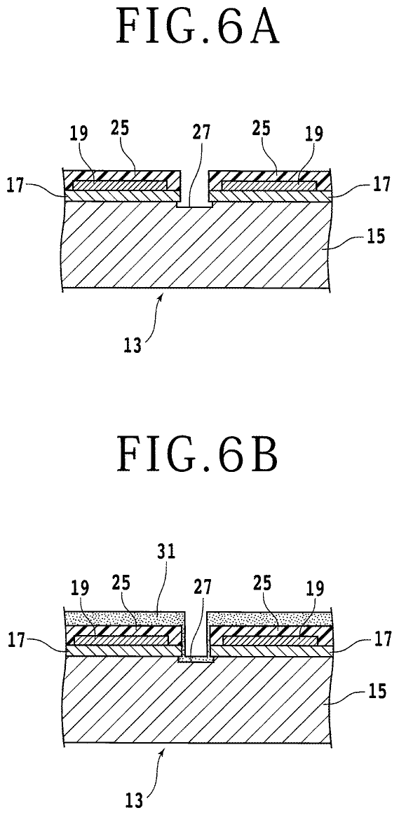

As a result, the first plasma etching step (S3) is completed. FIG. 6A is a partial enlarged sectional view depicting schematically the wafer 13 after the first plasma etching step (S3).

In the first plasma etching step (S3), the wafer 13 is subjected to isotropic etching by F-based radicals or the like generated in the inside space of the chamber 22. As a result, the damaged portions 29 in the vicinity of the side surfaces and the bottom surfaces of the grooves 27 formed in the front surface of the wafer 13 are removed.

After the first plasma etching step (S3), the side surfaces and the bottom surfaces of the grooves 27 formed in the front surface of the wafer 13 are coated with a second protective film (second coating step: S4). The second coating step (S4) is carried out, for example, as follows by utilizing the above-described plasma generating apparatus 20.

Specifically, first, in a state in which the wafer 13 is held by the electrostatic chuck of the table 32 through the tape 21, the inside space of the chamber 22 is exhausted to establish a vacuum state. Next, in a state in which a gas containing C₄F₈ is supplied from the gas supply source 48a into the inside space of the chamber 22 and an Ar gas is supplied from the gas supply source 48b into the inside space of the chamber 22, high-frequency electric power is supplied from the high-frequency power source 44 to the gas ejecting head 40, over a predetermined period of time.

As a result, the second coating step (S4) is completed. FIG. 6B is a partial enlarged sectional view depicting schematically the wafer 13 after the second coating step (S4). In the second coating step (S4), a second protective film 31 having an insulating property is formed on the front surface side of the wafer 13.

Specifically, CF radicals are deposited on the upper surface of the first protective film 25 and the side surfaces and the bottom surfaces of the grooves 27, whereby a film containing carbon fluoride is formed. Note that it is preferable that the thickness of the second protective film 31 be 20 nm or more, so as to restrain the progress of the undercut at a time of dividing the wafer 13.

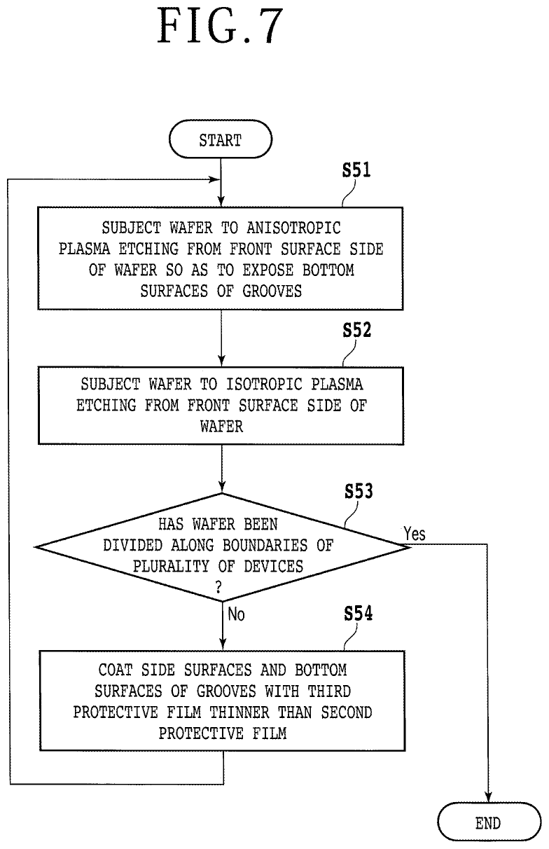

After the second coating step (S4), the wafer 13 is divided along the boundaries of the plurality of devices 19 by utilizing plasma etching (dividing step: S5). FIG. 7 is a flow chart depicting schematically a specific example of the dividing step (S5).

Specifically, in the dividing step (S5) depicted in FIG. 7, the wafer 13 is divided by utilizing what is generally called Bosch process.

This dividing step (S5) is carried out, for example, as follows by utilizing the above-described plasma generating apparatus 20. Specifically, first, in a state in which the wafer 13 is held by the electrostatic chuck of the table 32 through the tape 21, the inside space of the chamber 22 is exhausted, to establish a vacuum state.

Next, the wafer 13 is subjected to anisotropic plasma etching from the front surface side of the wafer 13 so as to expose the bottom surfaces of the grooves 27 formed in the front surface of the wafer 13 (second plasma etching step: S51).

Specifically, in a state in which a gas containing SF₆ is supplied from the gas supply source 48a into the inside space of the chamber 22 and an Ar gas is supplied from the gas supply source 48b into the inside space, high-frequency electric power is supplied from the high-frequency power source 36 to the electrode 32a provided inside the table 32, and high-frequency electric power is supplied from the high-frequency power source 44 to the gas ejecting head 40, over a predetermined period of time.

In the second plasma etching step (S51), F-based ions and the like generated in the inside space of the chamber 22 are accelerated toward the table 32, whereby the wafer 13 is anisotropically etched. As a result, of the second protective film 31, the portions covering the side surfaces of the grooves 27 are left, whereas the portions covering the bottom surfaces of the grooves 27 are removed, so that the bottom surfaces of the grooves 27 are exposed.

Next, the wafer 13 is subjected to isotropic plasma etching from the front surface side of the wafer 13 (third plasma etching step: S52). Specifically, in a state in which a gas containing SF₆ is supplied from the gas supply source 48a into the inside space of the chamber 22 and an Ar gas is supplied from the gas supply source 48b into the inside space, high-frequency electric power is supplied from the high-frequency power source 44 to the gas ejecting head 40, over a predetermined period of time.

In this third plasma etching step (S52), similarly to the first plasma etching step (S3), the wafer 13 is isotropically etched by F-based radicals and the like generated in the inside space of the chamber 22. As a result, the portions in the vicinity of the bottom surfaces of the grooves 27 which are exposed are isotropically removed.

If the wafer 13 is not divided along the boundaries of the plurality of devices 19 in the third plasma etching step (S52) (S53: No), the side surfaces and the bottom surfaces of the grooves 27 are coated with a third protective film thinner than the second protective film 31 (third coating step: S54).

Specifically, in a state in which a gas containing C₄F₈ is supplied from the gas supply source 48a into the inside space of the chamber 22 and a gas containing Ar is supplied from the gas supply source 48b into the inside space, high-frequency electric power is supplied from the high-frequency power source 44 to the gas ejecting head 40, over a predetermined period of time.

In the third coating step (S54), CF radicals are deposited on the side surfaces and the bottom surfaces of the grooves 27, whereby a film containing carbon fluoride is formed. Note that the thickness of the third protective film is, for example, 10 nm or less.

Further, in the dividing step (S5) depicted in FIG. 7, the second plasma etching step (S51), the third plasma etching step (S52), and the third coating step (S54) are repeated until the wafer 13 is divided along the boundaries of the plurality of devices 19.

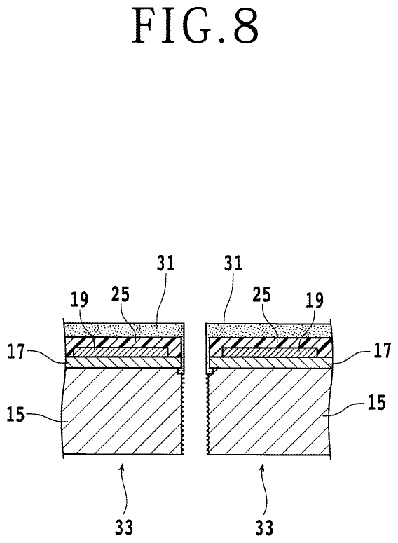

When the wafer 13 has been divided along the boundaries of the plurality of devices 19 (S53: Yes), a plurality of chips are formed. FIG. 8 is a partial enlarged sectional view depicting schematically the chips manufactured from the wafer 13 divided in the dividing step (S5) depicted in FIG. 7. When the wafer 13 is divided by the dividing step (S5) depicted in FIG. 7, the chips 33 with irregular side surfaces are manufactured.

In the above-described chip manufacturing method, after the damaged portions 29 in the vicinity of the side surfaces and the bottom surfaces of the grooves 27 formed in the groove forming step (S2) are removed in the first plasma etching step (S3), the side surfaces of the grooves 27 are coated with the second protective film 31 formed in the second coating step (S4). As a result, it is possible to prevent the undercut which would progress from the side surfaces of the grooves 27, in the dividing step (S5) in which the wafer 13 is subjected to plasma etching.

Note that the contents of the above description are one mode of the present invention, and the contents of the present invention are not limited to the contents of the above description. For example, the wafer utilized in the present invention may be a wafer which does not include the insulating layer 17 and in which the devices 19 are formed directly on the front surface of the substrate 15.

In addition, in the above-described second coating step (S4), an oxide film formed by utilizing oxygen plasma may be utilized as the second protective film. Specifically, in the above-described second coating step (S4) described above, the second protective film may be formed by supplying high-frequency electric power from the high-frequency power source 44 to the gas ejecting head 40, in a state in which a gas containing O₂ and Ar is supplied from the gas supply source 48b into the inside space of the chamber 22, over a predetermined period of time. In this case, an oxide film formed by a reaction between a material (for example, silicon) constituting the wafer 13 and oxygen ions at the side surfaces and the bottom surfaces of the grooves 27 can be utilized as the second protective film.

In addition, in the above-described dividing step (S5), the conditions for anisotropic plasma etching for removing the second protective film 31 covering the bottom surfaces of the grooves 27 to expose the bottom surfaces and the conditions for anisotropic plasma etching for removing the third protective film covering the bottom surfaces of the grooves 27 to expose the bottom surfaces may be different from each other.

In other words, in the above-described dividing step (S5), in the second plasma etching step (S51) carried out first and the second plasma etching step (S51) carried out for the second time and later, the conditions for anisotropic plasma etching may be different. For example, the predetermined period of time over which the second plasma etching step (S51) is carried out first may be longer than the predetermined period of time over which the second plasma etching step (S51) is carried out for the second time and later.

Besides, in the above-described dividing step (S5), the wafer 13 may be divided without carrying out the third plasma etching step (S52) and the third coating step (S54). Specifically, in the above-described dividing step (S5), the wafer 13 may be subjected to anisotropic plasma etching from the front surface side of the wafer 13, until the wafer 13 is divided along the boundaries of the plurality of devices 19.

In addition, in a case where only the anisotropic plasma etching is carried out in the dividing step (S5), the conditions for the anisotropic plasma etching for removing the second protective film 31 covering the bottom surfaces of the grooves 27 to expose the bottom surfaces and the conditions for the anisotropic plasma etching for removing the regions overlapping with the boundaries of the plurality of devices 19 of the wafer 13 to divide the wafer 13 may be different from each other.

Besides, a structure, a method, and the like according to the above embodiment may be appropriately modified, and various modifications can be implemented without departing from the scope of the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A chip manufacturing method for dividing a wafer formed with a plurality of devices along boundaries of the plurality of devices to manufacture individual chips, the chip manufacturing method comprising:
a first coating step of coating a front surface of the wafer with a water-soluble first protective film;
a groove forming step of applying a laser beam of such a wavelength as to be absorbed in the wafer to the wafer through the first protective film such that regions of the first protective film overlapping with the boundaries and regions on the front surface side of the wafer overlapping with the boundaries are removed and grooves are formed in the wafer, after the first coating step;
a first plasma etching step of subjecting the wafer to isotropic plasma etching from the front surface side of the wafer in a state in which the grooves are exposed, after the groove forming step;
a second coating step of coating side surfaces and bottom surfaces of the grooves with a second protective film, after the first plasma etching step; and
a dividing step of sequentially repeating, after the second coating step, a second plasma etching step of subjecting the wafer to anisotropic plasma etching from the front surface side of the wafer so as to expose the bottom surfaces of the grooves, a third plasma etching step of subjecting the wafer to isotropic plasma etching from the front surface side of the wafer, and a third coating step of coating the side surfaces and the bottom surfaces of the grooves with a third protective film thinner than the second protective film, until the wafer is divided along the boundaries.

2. A chip manufacturing method for dividing a wafer formed with a plurality of devices along boundaries of the plurality of devices to manufacture individual chips, the chip manufacturing method comprising:
a first coating step of coating a front surface of the wafer with a water-soluble first protective film;
a groove forming step of applying a laser beam of such a wavelength as to be absorbed in the wafer to the wafer through the first protective film such that regions of the first protective film overlapping with the boundaries and regions on the front surface side of the wafer overlapping with the boundaries are removed and grooves are formed in the wafer, after the first coating step;
a first plasma etching step of subjecting the wafer to isotropic plasma etching from the front surface side of the wafer in a state in which the grooves are exposed, after the groove forming step;
a second coating step of coating side surfaces and bottom surfaces of the grooves with a second protective film, after the first plasma etching step; and
a dividing step of subjecting the wafer to anisotropic plasma etching from the front surface side of the wafer, until the wafer is divided along the boundaries, after the second coating step.

3. The chip manufacturing method according to claim 2, further comprising:
a second plasma etching step of subjecting the wafer to anisotropic plasma etching from the front surface side of the wafer so as to expose the bottom surfaces of the grooves, after the second coating step and before the dividing step,
wherein conditions for the anisotropic plasma etching are different between the second plasma etching step and the dividing step.

4. The chip manufacturing method according to claim 1,
wherein the wafer includes a substrate, and an insulating layer provided between the substrate and the plurality of devices.

5. The chip manufacturing method according to claim 1, wherein the second protective film has an insulating property.

6. The chip manufacturing method according to claim 1,
wherein the second protective film contains carbon fluoride.

7. The chip manufacturing method according to claim 1,
wherein a thickness of the second protective film is 20 nm or more.
